(19) United States
(12) Patent Application Publication
(10) Pub. No.: US 2009/0212324 A1
(43) Pub. Date: Aug. 27, 2009

(54) HETEROJUNCTION FIELD EFFECT TRANSISTOR

(75) Inventors: Isao TAMAI, Tokyo (JP); Fumihiko Toda, Tokyo (JP); Shinichi Hoshi, Tokyo (JP)

Correspondence Address: MOTS LAW, PLLC, 1629 K STREET N.W., SUITE 602, WASHINGTON, DC, 20006-1635, US

(73) Assignee: OKI Electric Industry Co., Ltd., Tokyo (JP)

(21) Appl. No.: 12/366,871

(22) Filed: Feb. 6, 2009

(30) Foreign Application Priority Data
Feb. 26, 2008 (JP) JP2008-044649

(51) Int. Cl. H01L 29/772

(52) U.S. Cl. 257/192; 257/E29.242

(57) ABSTRACT

An aspect of the invention provides a heterojunction field effect transistor that comprises: a base; a first GaN channel layer formed on the base; an AlN electron supply layer formed on the first GaN layer, and a second GaN cap layer formed on the AlN layer.

### CROSS REFERENCE TO RELATED APPLICATIONS

This application claims priority based on 35 USC 119 from prior Japanese Patent Application No. P2008-044649 filed on Feb. 26, 2008, the entire contents of which are incorporated herein by reference.

### BACKGROUND OF THE INVENTION

1. Field of the Invention

The present invention relates to a heterojunction field effect transistor, and more specifically to a gallium nitride high electron mobility transistor.

2. Description of Related Art

Referring to FIG. 9, a heterojunction field effect transistor of the related art is described. FIG. 9 is a schematic view for illustrating a heterojunction field effect transistor of the related art and shows a cut end surface of an essential part thereof.

Heterojunction field effect transistor 110 is configured by sequentially forming, on base 120, the GaN layer acting as channel layer 140 and the AlGaN layer acting as electron supply layer 150. Heterojunction field effect transistor 110 has a heterostructure formed of an AlGaN layer acting as electron supply layer 150 and a GaN layer acting as channel layer 140. In this structure, a two-dimensional electron gas (2DEG) with high density and high electron mobility is formed at heterointerface 142, which is an interface between channel layer 140 and electron supply layer 150. Accordingly, the heterojunction field effect transistor 110 shows preferable characteristics as a high electron mobility transistor. In the following description, a heterojunction field effect transistor with an AlGaN/GaN heterostructure, which is a type of a high electron mobility transistor, is also referred to as an AlGaN/GaN high electron mobility transistor (AlGaN/GaN-HEMT).

Source electrode 182 and drain electrode 184, which are formed with ohmic contact, and gate electrode 180 formed with Schottky junction are provided on electron supply layer 150. AlGaN/GaN-HEMT 110 is separated from other devices by, for example, device isolation regions 135 formed by doping impurities into channel layer 140 and electron supply layer 150. A silicon nitride film is formed as surface protection film 190 on upper surface 152 of electron supply layer 150.

For example, if electron supply layer 150 is formed of AlₓGa₁₋ₓN (x=0.25) and the thickness (active layer thickness) (a) of electron supply layer 150 is 25 nm, the 2DEG density is approximately 1.0×10¹³ cm⁻² and the electron mobility is 1500 cm²/V·s.

To provide a higher frequency transistor, an increased cut-off frequency (f_{T}) is effective. As the most effective measure to increase the cut-off frequency f_{T}, shortening gate length (Lg) is known.

However, shortening the gate length Lg causes so-called short channel effects, such as deterioration of pinch-off characteristics and a negative shift of threshold voltage. The deterioration of pinch-off characteristics in a field effect transistor (FET) decrease operating voltage of the FET while the shift of threshold voltage in a FET narrows the tolerance ranges for design values, and thus affects yield or the like of the FET.

In order to prevent this short channel effect, it is desirable that the ratio between the active layer thickness a and gate length (Lg) (aspect ratio Lg/a) be five (5) or more. This is disclosed, for example, by Masumi Fukuda and Yasutake Hirachi in their “Basics on GaAs field effect transistor,” Corona Publishing, 1992, pp. 56-59.

In AlGaN/GaN-HEMT 110 describe above, since the active layer thickness (a) is 25 nm, the aspect ratio Lg/a is approximately four (4) in a short gate region with a gate length (Lg) of 0.1 μm. Thus, the short channel effect is caused in the short gate region.

Here, when the active layer thickness (a) is decreased, that is, electron supply layer 150 is thinned, the 2DEG density is decreased in the FET. To address this problem, when “x” in AlₓGa₁₋ₓN is increased, that is, when the concentration of aluminum is increased, until AlₓGa₁₋ₓN becomes AlN, the thickness of electron supply layer 150 can be theoretically reduced to ¼ or less, compared with the thickness of electron supply layer 150 formed of AlₓGa₁₋ₓN (x=0.25). However, if AlGaN is grown by metal organic chemical vapor deposition (MOCVD) method and the concentration of aluminum in AlₓGa₁₋ₓN increased, cracks are caused in the surface of the AlGaN layer at approximately x=0.52. These cracks affect the FET characteristics. This is disclosed by, for example, M. Miyoshi et al., “Characterization of Different-Al-Content AlGaN/GaN Heterostructures and High-Electron-Mobility Transistors Grown on 100-mm-Diameter Sapphire Substrates by Metalorganic Vapor Phase Epitaxy”, Jpn. J. Appl. Phys., Vol. 43, No. 12, 2004, pp. 7939-7943.

Similar to AlₓGa₁₋ₓN with the aluminum concentration increased to x=0.52 or more, when AlN is grown by the MOCVD method, cracks are caused in the surface of the AlN layer even with its thickness of approximately 2 nm.

Although the reason of crack formation is not clear, an AlN layer or an AlₓGa₁₋ₓN layer with x=0.6 or more cannot be used for electron supply layer 150 due to these cracks.

Meanwhile, in processes for forming the AlN layer, plasma assisted molecular beam epitaxy (PAMBE) method may be employed in place of the MOCVD method. This is disclosed by M. Higashiwaki et al., “AlN/GaN Insulated-Gate HFETs Using Cat-CVD SiN”, IEEE ELECTRON DEVICE LETTERS, Vol. 27, No. 9, 2006, pp. 719-721 (hereinafter, abbreviated as Higashiwaki).

Higashiwaki discloses that AlN can be grown without causing cracks by the PAMBE method because a temperature of growing AlN used in the PAMBE method is in a low range of 200° C. to 300° C.

### SUMMARY OF THE INVENTION

An aspect of the invention provides a heterojunction field effect transistor that comprises a base; a first GaN channel layer formed on the base; an AlN electron supply layer formed on the first GaN layer, and a second GaN cap layer formed on the AlN layer.

As an embodiment of the heterojunction field effect transistor, it is preferable that a silicon nitride film serving as a surface protection film be formed on the second GaN layer. In addition, it is preferable that the AlN layer be formed by a metal organic chemical vapor deposition method. Furthermore, it is suitable that the thickness of the AlN layer be 5 nm or less.

As an alternative Higashiwaki teaches forming an AlN layer with a thickness of approximately 2.5 nm as an electron supply layer. However, the obtained electron mobility was approximately 365 cm²/V·s, which is only about ¼ of 1500 cm²/V·s that can be obtained when AlGaN is used for an electron supply layer.

The inventors closely studied and found that large electron mobility is obtained by forming, using the MOCVD method, an AlN layer as an electron supply layer with a thickness of 2.5 nm to 8 nm and further forming a GaN layer as a cap layer on the AlN layer, and unpredictable results were obtained.

### BRIEF DESCRIPTION OF THE DRAWINGS

FIG. 1 is a schematic view for illustrating a heterojunction field effect transistor, according to an embodiment of the invention;

FIGS. 2A to 2C are views that illustrate surface states when states of top surfaces are changed;

FIG. 3 is a graph for illustrating a surface roughness when a state of the top surface is changed;

FIGS. 4A to 4E are AFM images of AlN layers with different thicknesses;

FIG. 5 is a graph showing a relationship between the thickness of the AlN layer and the surface roughness;

FIG. 6 is a characteristic chart showing dependencies of sheet carrier density, electron mobility, and sheet resistance on the thickness of the AlN layer;

FIG. 7 is a characteristic chart showing dependencies of surface roughness and electron mobility on the thickness of the AlN layer; and

FIG. 8 is a schematic view that illustrates a heterojunction field effect transistor according to another embodiment.

FIG. 9 is a schematic view that illustrates a heterojunction field effect transistor according to related art.

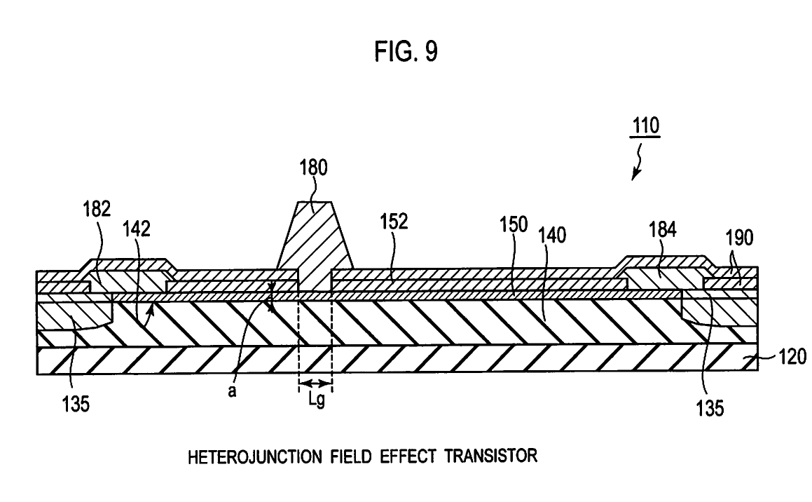

### DETAILED DESCRIPTION OF EMBODIMENT

An embodiment of the invention will be described below by referring to the drawings. However, shapes, sizes, and positional relationships of respective components are merely schematically shown to an extent that the invention would be understood. In addition, the preferred embodiment will be described below. However, materials, numerical conditions or the like of the respective components are simply shown as a preferred embodiment. Accordingly, the invention is not limited by the following embodiment but various modifications and deformation that can achieve the effects of the invention can be made without departing from the scope of the invention.

Prepositions, such as “on”, “over” and “above” may be defined with respect to a surface, for example a layer surface, regardless of that surface's orientation in space. The preposition “above” may be used in the specification and claims even if a layer is in contact with another layer. The preposition “on” may be used in the specification and claims when a layer is not in contact with another layer, for example, when there is an intervening layer between them.

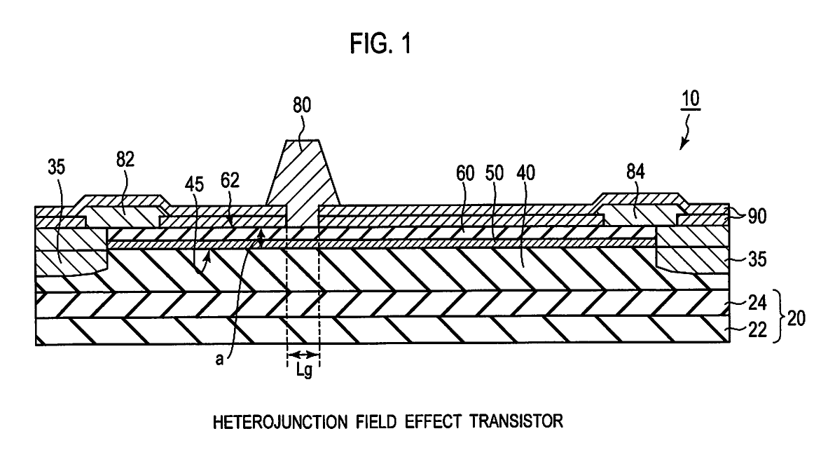

Referring to FIG. 1, a heterojunction field effect transistor according to an embodiment is described. Note that this heterojunction field effect transistor is a high-electron mobility transistor (HEMT) and is referred to as the HEMT in the following description.

FIG. 1 is a schematic view for illustrating AlN/GaN-HEMT as the heterojunction field effect transistor according to the embodiment, and shows a cut end surface of an essential part thereof.

Heterojunction field effect transistor 10 according to the embodiment includes channel layer 40, electron supply layer 50, and cap layer 60, which are sequentially formed on base 20.

Base 20 is configured by including buffer layer 24 on crystal growth substrate 22.

In the embodiment, a silicon carbide (SiC) substrate is used for crystal growth substrate 22. Note that a silicon substrate or a sapphire substrate may be used for crystal growth substrate 22, as in the case with a substrate generally used in a heterojunction field effect transistor.

Buffer layer 24 is provided so as to effect a lattice relaxation between crystal growth substrate 22 and channel layer 40. Buffer layer 24 is formed with a thickness of approximately 100 nm by growing, for example, AlN using a metal organic chemical vapor deposition method (MOCVD method).

Channel layer 40, electron supply layer 50, and cap layer 60 are formed sequentially by using the MOCVD method, similar to forming buffer layer 24.

A GaN layer (first GaN layer) with a thickness of approximately 1000 nm is formed as channel layer 40. In addition, an AlN layer is formed as electron supply layer 50. Furthermore, a GaN layer (second GaN layer) with a thickness of approximately 2.5 nm is formed as cap layer 60. The thickness of electron supply layer 50 is described later.

In a particularly desirable embodiment, a step of depositing silicon nitride film by MOCVD after formation of channel layer 40, electron supply layer 50, and cap layer 60 is carried out.

Here, two-dimensional electron gas (2DEG) is formed at AlN/GaN heterointerface 45, which is an interface between the first GaN layer as channel layer 40 and the AlN layer as electron supply layer 50.

Surface protection film 90 is provided on the cap layer 60. For example, a silicon nitride film is formed for surface protection film 90. The silicon nitride film may be formed by any suitable method, such as plasma CVD method or thermal CVD method, and it is preferable that the silicon nitride film be subsequently deposited by the MOCVD method in a same manufacturing device after channel layer 40, electron supply layer 50, and cap layer 60 are formed.

AlN/GaN-HEMT 10 includes electrodes, each of which is formed in an opening provided in surface protective film 90. For example, source electrode 82 and drain electrode 84 are formed as ohmic electrodes, while gate electrode 80 is formed as a Schottky electrode. These electrodes may be formed by a conventional technique, such as lift-off method, and the description thereof will not be given here.

In addition, AlN/GaN-HEMT 10 is separated from other devices by device isolation region 35 formed, for example, by doping impurities into channel layer 40 and electron supply layer 50.

The AlN layer contains much Al. Thus, the AlN layer easily receives surface oxidation damage and cracks are caused. For this reason, when an AlN layer is exposed to an atmosphere, it is difficult to suppress the gate leakage current. In AlN/GaN-HEMT 10 according to the embodiment, the AlN layer acting for electron supply layer 50 is covered with the second GaN layer formed as cap layer 60. Thereby, oxidation at the surface of electron supply layer 50 can be suppressed.

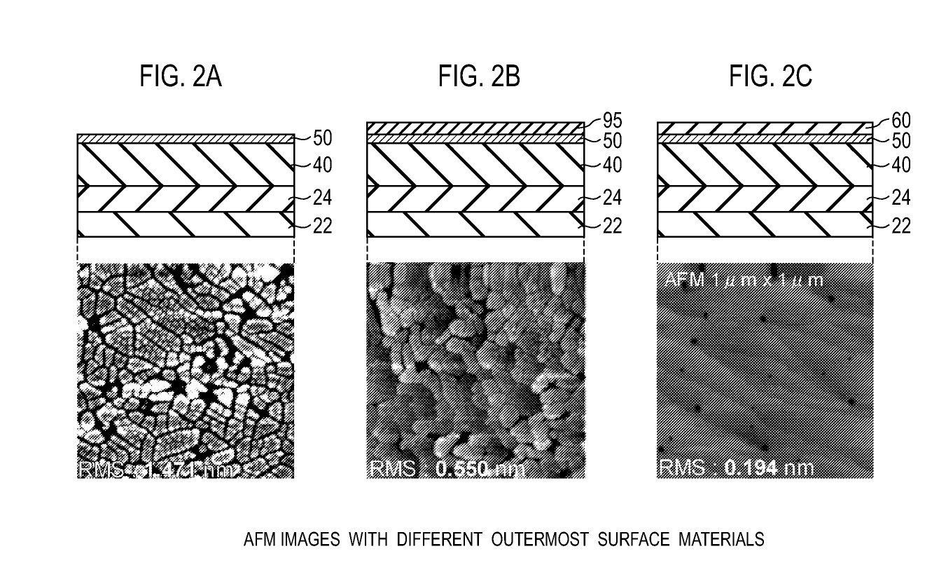

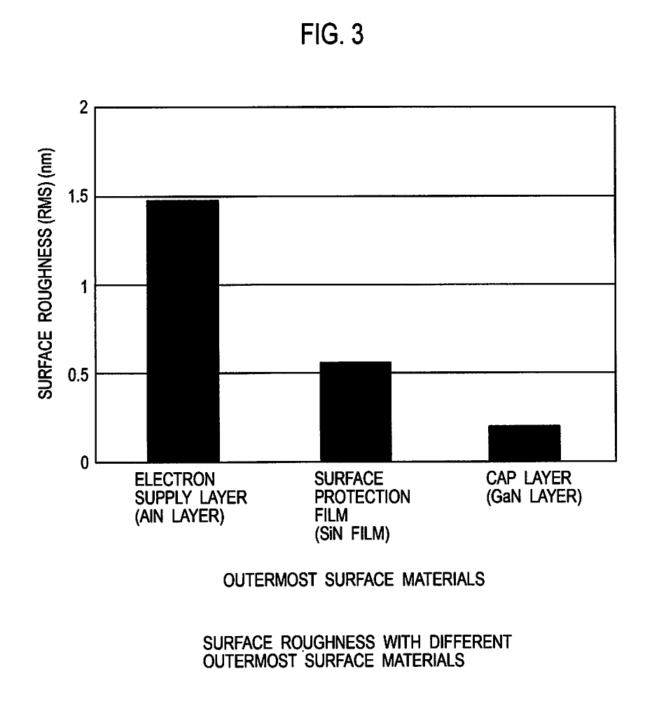

Referring to FIGS. 2 and 3, the surface roughness with different states of the upper surfaces of electron supply layer 50 is described below. The surface roughness is used for evaluating flatness of the surface. The distribution of positions of the surfaces in the height direction is calculated as a root mean square (RMS) of a distance from the average position.

FIGS. 2A to 2C show schematic views of three types of structures, each exposing different materials on the upper surface (outermost surface materials) and the respective images observed by an atomic force microscope (AFM). FIG. 3 is a graph that shows measurement results of the surface roughness in relation to these three kinds of structures.

Here, the structures of crystal growth substrate 22, buffer layer 24, channel layer 40, and electron supply layer 50 are the same in the three kinds of structures. The AlN layer with the thickness of 100 nm as buffer layer 24, the first GaN layer with the thickness of 1000 nm as channel layer 40, the AlN layer with the thickness of 2.5 nm as electron supply layer 50 are formed on crystal growth substrate 22.

FIG. 2A shows a first example wherein the surface protection film or the like is not formed on electron supply layer 50, that is, the case where the AlN layer is the outermost surface. In this case, cracks are formed in the surface as shown in the AFM image. The surface roughness of electron supply layer 50 in the first example is measured at 1.471 nm (FIG. 3).

FIG. 2B shows a second example wherein a silicon nitride film with the thickness of 13 nm is formed as surface protection film 95 on electron supply layer 50. The surface state is somewhat improved by providing surface protection film 95. However, cracks are still formed. The surface roughness of electron supply layer 50 in the second example is measured at 0.550 nm (FIG. 3).

FIG. 2C shows a third example wherein the second GaN layer is formed with a thickness of 2.5 nm on electron supply layer 50 as cap layer 60. When cap layer 60 is provided, the surface state of electron supply layer 50 is further improved when compared with the second example that the silicon nitride film is formed at the top surface as shown in FIG. 2B and cracks are not caused. The surface roughness of electron supply layer 50 in the third example is measured at 0.194 nm (FIG. 3).

The surface state is further improved by providing the second GaN layer on the AlN layer, than second example where the silicon nitride film is provided. The reason for this improvement is possibly that effects, such as the suppression of surface oxidation of the AlN layer in addition to the suppression of lattice mismatch of AlN/GaN, can be obtained by providing the second GaN layer.

In this manner, to obtain a preferable surface state, it is better to provide the second GaN layer acting for cap layer 60 on the AlN layer acting for electron supply layer 50.

Next, the thickness of electron supply layer 50 is described below. Note that, in the following description, the thickness of electron supply layer 50, that is, the thickness of the AlN layer indicates the designed values. In some instances, the actual measurements after manufacture indicate dispersion of approximately 20% in relation to the designed value due to the nonuniformity in manufacture.

In order to increase the 2DEG density, it is better to further increase the thickness of the AlN layer acting for electron supply layer 50. Lattice constants of AlN and GaN are respectively 3.112 Å and 3.187 Å, which have a difference of approximately 2.4%. Thus, the critical thickness of the AlN layer with which the AlN layer can be formed without causing cracks is approximately 10 nm theoretically.

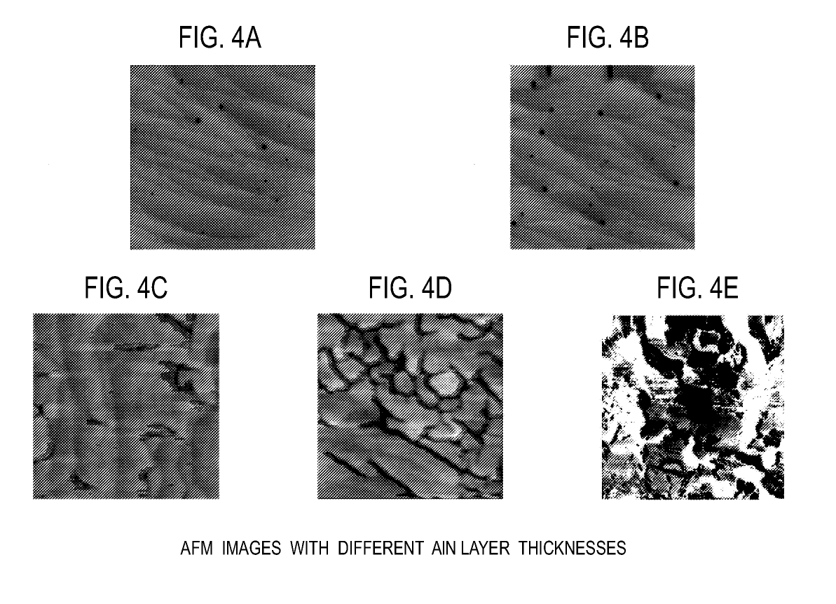

FIGS. 4A to 4E show AFM images when the thicknesses of AlN layers are respectively 0.5 nm, 2.5 nm, 6 nm, 8 nm, and 20 nm. Here, the surface of the second GaN layer formed on the AlN layer is shown by the AFM image in a region with 1 square μm.

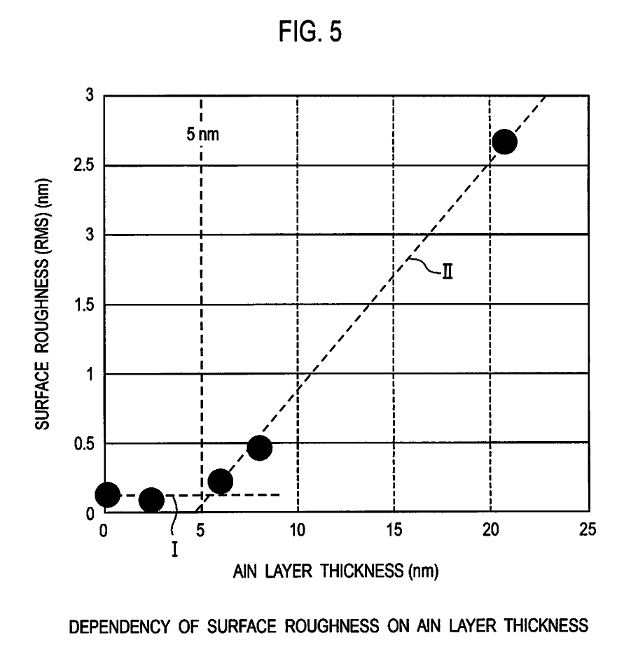

In addition, FIG. 5 shows a relationship between the thickness of the AlN layer and the surface roughness. In FIG. 5, the AlN layer thickness (unit: nm) is measured along the horizontal axis and the surface roughness (RMS) (unit: nm) is measured along the longitudinal axis.

Cracks are not caused in the surface when the thickness of the AlN layer is 2.5 nm or less (FIGS. 4A and B), and the surface roughness is measured at 0.2 nm or less (FIG. 5). When the thickness of the AlN layer increases to 6 nm, cracks are caused in the surface. As the thickness of the AlN layer becomes larger, cracks become obvious (FIGS. 4C, 4D, and 4E).

It can be seen from the relationship between the thickness of the AlN layer and the surface roughness shown in FIG. 5 that the surface roughness linear-functionally increases in relation to the thickness of the AlN layer in a region with the thickness of AlN layer being 6 nm or more. In contrast, the surface roughness has a substantially constant value when the thickness of the AlN layer is 2.5 nm or less.

When two lines are drawn, that is, straight line I passing through two points where the thicknesses of the AlN layer are 0.5 nm and 2.5 nm and approximate straight line II passing through three points where the thicknesses of the AlN layer are 6 nm, 8 nm, and 20 nm, straight line I and approximate straight line II intersect with respect to each other in a point where the thickness of the AlN layer is approximately 5 nm.

Accordingly, it is likely that if the thickness of the AlN layer acting for the electron supply layer is set to 5 nm or less, a preferable surface state which has surface roughness of 0.2 nm or less can be obtained.

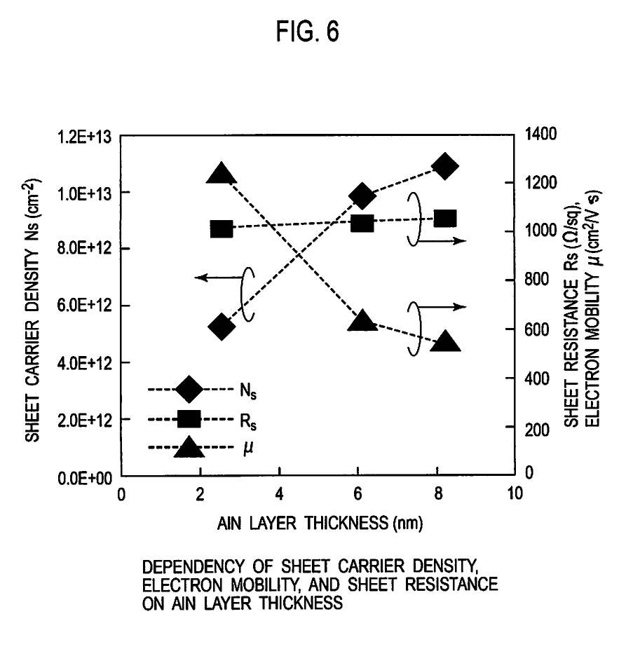

Next, referring to FIG. 6, sheet carrier density Ns, electron mobility μ, and sheet resistance Rs in relation to the thickness of the AlN layer 50 is described below. FIG. 6 is a characteristic chart showing dependencies of sheet carrier density Ns, electron mobility μ, and sheet resistance Rs on the thickness of the AlN layer 50. In FIG. 6, the thickness of the AlN layer (unit: nm) is measured along the horizontal axis and the sheet carrier density Ns (cm⁻²), the sheet resistance Rs (Ω/sq), and the mobility u (cm²/V·s) are measured along the longitudinal axis.

Here, when the thickness of the AlN layer is 0.5 nm, carriers cannot be observed. This is possibly because the AlN/GaN heterojunction has a heterogeneous structure. In addition, when the thickness of the AlN layer is 20 nm, Hale measurements cannot be performed. This is possibly caused due to the surface roughness.

When the thicknesses of the AlN layer are 2.5 nm, 6 nm, and 8 nm, the electron mobility u is 500 cm²/V·s or more in any case. That is, more preferable results can be obtained, compared with values shown in Higashiwaki. In particular, when the thickness of the AlN layer is 2.5 nm, the electron mobility μ shows an extremely high value of 1226.8 cm²/V·s, which value approximates the value (1500 cm²/V·s) obtained in the AlₓGa₁₋ₓN (x=0.25)/GaN heterostructure.

The sheet resistance Rs does not show any dependency on the thickness of the AlN layer and shows a substantially constant value. In addition, the sheet carrier density Ns increases as the thickness of the AlN layer increases.

Judging from FIGS. 5 and 6, it is likely that the value of electron mobility μ greatly relates to the surface roughness, that is, the surface state. When the surface roughness is increased, that is, when the surface state is deteriorated, a tendency is observed that the electron mobility μ rapidly decrease without forming a preferable heterointerface.

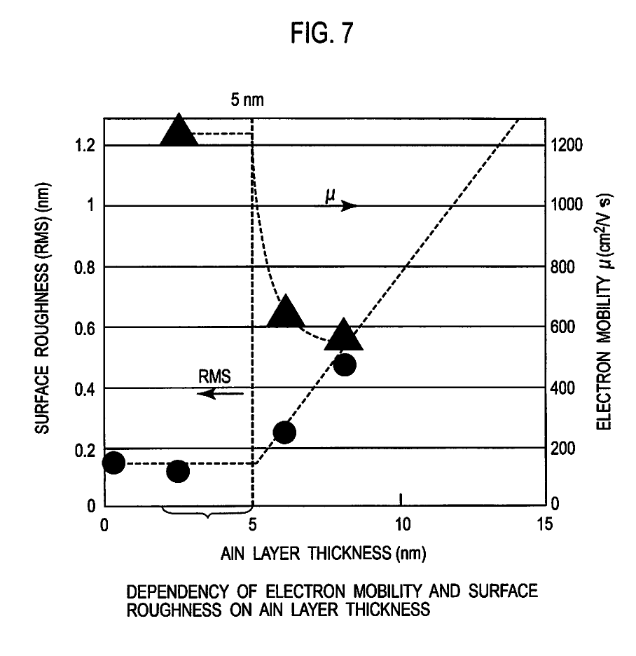

FIG. 7 shows dependencies of the surface roughness and the electron mobility on the thickness of the AlN layer 50. In FIG. 7, the thickness of the AlN layer (unit: nm) is measured along the horizontal axis and the surface roughness (RMS) (unit: nm) and the electron mobility μ (cm²/V·s) are measured along the longitudinal axis. The surface roughness increases and the electron mobility μ decreases when the thickness of the AlN layer increases.

From these results, when the second GaN layer acting for the cap layer 60 is provided on the AlN layer acting for the electron supply layer 50 and, furthermore, the thickness of the AlN layer 50 is set to be at least 2.5 nm and not more than 8 nm, the AlN/GaN-HEMT 10 with electron mobility higher than that of the AlN/GaN-HEMT in the related art can be obtained. Furthermore, if the thickness of the AlN layer 50 is set to be 5 nm or less, high electron mobility, which is approximate to the electron mobility of AlₓGa₁₋ₓN (x=0.25)/GaN-HEMT can be obtained.

In the above-described embodiment, the example of the heterojunction field effect transistor in which gate electrode 80 is formed as a Schottky electrode on cap layer 60 has been described. However, the invention is not limited to this configuration.

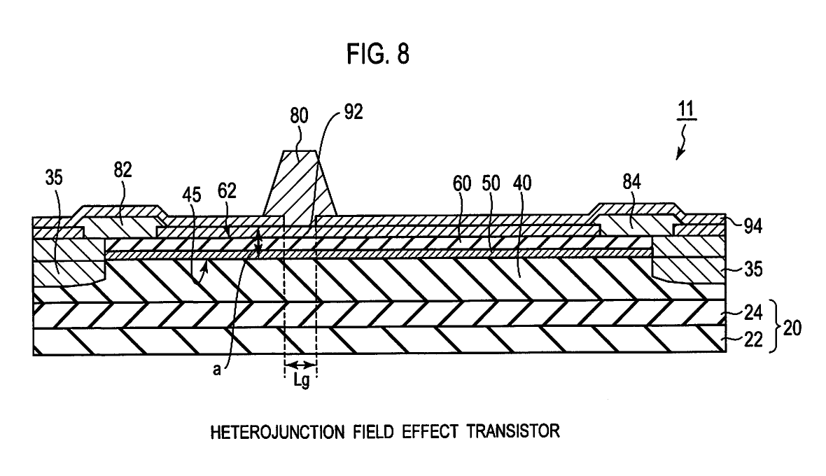

FIG. 8 is a schematic view for illustrating AlN/GaN-HEMT as the heterojunction field effect transistor according to another embodiment. The heterojunction field effect transistor 11 may be a field effect transistor with a so-called metal insulator semiconductor (MIS) structure (MISFET). The MISFET 11 is configured in such a manner that, for example, a silicon nitride film 92 is provided as a gate insulating film on cap layer 60 and a gate electrode is provided on gate insulating film 92. The MISFET 11 includes Surface protection film 94 provided on gate insulating film 92 and source electrode 82 and drain electrode 84. The active layer thickness (a) includes thickness of AlN layer 50, cap layer 60, and gate insulating film 92. With the MIS structure, a gate leakage current can be suppressed.

The embodiment can provide a heterojunction field effect transistor that has high two-dimensional electron density and high electron mobility and does not cause a short channel effect.

According to the above-described heterojunction field effect transistor of the embodiment, favorable device characteristics, such as high two-dimensional electron density and high electron mobility, can be obtained.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

What is claimed is:

1. A heterojunction field effect transistor comprising:
a base;
a first GaN channel layer formed on the base;
an AlN electron supply layer formed on the first GaN layer, and
a second GaN cap layer formed on the AlN layer.

2. The transistor according to claim 1, wherein the first GaN channel layer, the AlN electron supply layer and the second GaN cap layer are sequentially formed by a manufacturing device.

3. The transistor according to claim 1, further comprising a silicon nitride surface protection film formed on the second GaN cap layer.

4. The transistor according to claim 1, wherein the base includes a crystal growth substrate and a buffer layer formed on the crystal growth substrate, wherein the buffer layer comprises AlN.

5. The transistor according to claim 2, wherein the silicon nitride surface protection film is formed in a same manufacturing device in which the first GaN channel layer, the AlN electron supply layer and the second GaN cap layer are formed, whereby the silicon nitride surface protection film, the first GaN channel layer, the AlN electron supply layer and the second GaN cap layer are sequentially formed.

6. The transistor according to claim 1, wherein the AlN layer is formed by a metal organic chemical vapor deposition method.

7. The transistor according to claim 1, wherein the thickness of the AlN layer is not more than 10 nm.

8. The transistor according to claim 1, wherein the thickness of the AlN layer is not more than 5 nm.

9. The transistor according to claim 1, wherein the thickness of the AlN layer is least 2.5 nm but not more than 8 nm

10. The transistor according to claim 1, wherein the thickness of the AlN layer is set in intersection of approximate straight line passing through points where a first thicknesses of the AlN layer and approximate straight line passing through points where a second thicknesses of the AlN layer that is thicker than the first thickness, where points are plotted in relationship between the thickness of AlN layer and a roughness of a surface of the AlN layer.

11. The transistor according to claim 1, wherein the silicon nitride surface protection film has an opening.

12. The transistor according to claim 11, further comprising a gate electrode formed in the opening provided in the silicon nitride surface protective film, the gate electrode is in contact with the second GaN cap layer.

13. The transistor according to claim 11, wherein the gate electrode is a Schottky electrode.

14. The transistor according to claim 1, further comprising:
a source electrode provided in contact with the second GaN cap layer; and
a drain electrode provided in contact with the second GaN cap layer.

15. The transistor according to claim 14, wherein the source electrode and the drain electrode are ohmic electrode.

16. The transistor according to claim 1, further comprising a device isolation region formed by doping an impurity into the first GaN channel layer and the AlN electron supply layer.

17. The transistor according to claim 11, further comprising a gate electrode formed in the opening provided in the silicon nitride surface protective film and a gate insulating layer formed under the gate electrode in the opening.

18. A heterojunction field effect transistor comprising:
a base;
a channel layer formed of a first martial, formed on the base;
an electron supply layer formed of a second martial, formed on the channel layer, and
a cap layer formed of a first martial, formed on the AlN layer, wherein the cap layer covers the entire top surface of the electron supply layer.

19. The transistor according to claim 18, wherein the channel layer, the electron supply layer and the cap layer are sequentially formed by a manufacturing device.

20. The transistor according to claim 18, further comprising a surface protection film formed of inert martial, formed on the cap layer.

21. The transistor according to claim 1, wherein the base includes a crystal growth substrate and a buffer layer formed on the crystal growth substrate, the buffer layer being formed of the second material.

22. The transistor according to claim 18, further comprising a silicon nitride surface protection film formed on the cap layer.

23. The transistor according to claim 22, wherein the silicon nitride surface protection film is formed in a same manufacturing device in which the channel layer, the electron supply layer and the cap layer are formed, whereby the silicon nitride surface protection film, the channel layer, the electron supply layer and the cap layer are sequentially formed.
